(19) United States
(12) Patent Application Publication
(10) Pub. No.: US 2018/0143271 A1
(43) Pub. Date: May 24, 2018

(54) MAGNETIC RESONANCE TRANSMITTING COIL AND MAGNETIC RESONANCE IMAGING APPARATUS

(71) Applicant: Shanghai Neusoft Medical Technology Co., Ltd., Shanghai (CN)

(72) Inventor: Qilin XU, Shanghai (CN)

(21) Appl. No.: 15/801,727

(22) Filed: Nov. 2, 2017

(30) Foreign Application Priority Data
Nov. 3, 2016 (CN) 201610971387.4

(51) Int. Cl. G01R 33/34; G01C 3/08

(52) U.S. Cl. CPC G01R 33/34084; G01C 3/08

(57) ABSTRACT

A magnetic resonance transmitting coil and a magnetic resonance imaging apparatus are provided. In one aspect, a magnetic resonance transmitting coil includes a base, a coil shield fixed on the base, a transmitting coil arranged in the coil shield and a regulator connected with the transmitting coil. An internal wall of the transmitting coil defines an accommodating space. The accommodating space of the transmitting coil may be adjusted by the regulator to fit a body shape of the subject so as to improve a transmitting efficiency of the transmitting coil.

### CROSS REFERENCE TO RELATED APPLICATIONS

This application claims priority to Chinese Patent Application No. 201610971387.4 filed on Nov. 3, 2016, the entire content of which is incorporated herein by reference.

### TECHNICAL FIELD

The present disclosure relates to magnetic resonance transmitting coils and magnetic resonance imaging apparatuses.

### BACKGROUND

Magnetic Resonance Imaging (MRI) apparatus is one of the most widely applied non-contact medical imaging apparatuses at present. An MRI apparatus is mainly used for clinical imaging diagnosis, where it may obtain an electromagnetic (EM) signal generated by magnetic resonance phenomenon, e.g., a magnetic resonance signal, from a human body and reconstruct an image based on the obtained EM signal.

A magnetic resonance transmitting coil, which is a core component of an MRI apparatus, serves to transmit a radio frequency (RF) signal to excite a subject to produce a magnetic resonance signal. A magnetic resonance transmitting coil can be designed such that legs of coils in the magnetic resonance transmitting coil are uniformly distributed. An accommodating space enclosed by an internal wall of a magnetic resonance transmitting coil may be fixed and serve to accommodate a subject and a scanning bed. The better the accommodating space enclosed by the internal wall of the magnetic resonance transmitting coil fits a body shape of the subject, the higher a transmission efficiency produced by the magnetic resonance transmitting coil is. However, due to the fixed internal wall of the magnetic resonance transmitting coil, different transmission efficiencies may be produced for subjects of different body shapes.

NEUSOFT MEDICAL SYSTEMS CO., LTD. (NMS), founded in 1998 with its world headquarters in China, is a leading supplier of medical equipment, medical IT solutions, and healthcare services. NMS supplies medical equipment with a wide portfolio, including CT, Magnetic Resonance Imaging (MRI), digital X-ray machine, ultrasound, Positron Emission Tomography (PET), Linear Accelerator (LINAC), and biochemistry analyser. Currently, NMS' products are exported to over 60 countries and regions around the globe, serving more than 5,000 renowned customers. NMS's latest successful developments, such as 128 Multi-Slice CT Scanner System, Superconducting MRI, LINAC, and PET products, have led China to become a global high-end medical equipment producer. As an integrated supplier with extensive experience in large medical equipment, NMS has been committed to the study of avoiding secondary potential harm caused by excessive X-ray irradiation to the subject during the CT scanning process.

### SUMMARY

The present disclosure provides a magnetic resonance transmitting coil that may fit different body shapes and an MRI apparatus containing the magnetic resonance transmitting coil. The shape and size of the magnetic resonance transmitting coil may be adjusted according to a body shape of a subject so that the transmitting coil may be closer to the subject and a distance between the transmitting coil and the subject can be kept in a particular range to obtain a higher transmission efficiency.

One aspect of the present disclosure features a magnetic resonance transmitting coil including: a base; a coil shield arranged on the base; a transmitting coil arranged in the coil shield and defining an accommodating space to accommodate a subject; and a regulator connected with the transmitting coil and configured to adjust the transmitting coil according to a shape of the subject such that the accommodating space of the transmitting coil fits the shape of the subject.

In some implementations, the transmitting coil includes: a coil body; a plurality of structural supports arranged on the coil body; and a guiderail disposed on respective peripheries of the structural supports, where the regulator is configured to adjust a distance between the transmitting coil and the subject by causing at least one of the structural supports to slide along the guiderail.

In some cases, before the transmitting coil is adjusted by the regulator, the structural supports are configured to be distributed on the coil body in an equal spacing. In some cases, when the accommodating space of the transmitting coil fits the shape of the subject, the spacing between two adjacent structural supports along an edge of the coil body decreases gradually from a top of the coil body to a bottom of the coil body. In some cases, the coil body includes a plurality of portions each being movable to the subject, and when the accommodating space of the transmitting coil fits the shape of the subject, a distance from each portion of the coil body to the subject is kept within a predetermined range.

At least one of a shape or a size of the guiderail can be changeable along with the adjustment of the transmitting coil. The plurality of structural supports can be configured to slide along the guiderail by locally stretching and retracting the transmitting coil.

In some implementations, the regulator includes: a driving motor; a transmission wheel connected with the driving motor; and a transmission component connected with the transmission wheel and the coil body. In some cases, the transmission component includes one of a plurality of cables connected to a plurality of portions of the coil body and structural connectors connected to the plurality of portions of the coil body. The transmission component can be configured such that, when the driving motor is controlled to drive the transmission wheel to rotate and then the transmission wheel drives the transmission component, the transmission component acts on the coil body to retract or release the coil body.

The magnetic resonance transmitting coil can further include one or more laser ranging devices disposed on the coil body and each configured to measure a distance from a portion of the coil body to the subject. One of the laser ranging devices can be located at a top of the coil body.

The magnetic resonance transmitting coil can further include a plurality of connectors fixed between the transmitting coil and the coil shield, and the connectors can be configured to keep a spacing between the transmitting coil and the coil shield to be fixed. A shape of the transmitting coil can include a D shape or an oval shape.

Another aspect of the present disclosure features a magnetic resonance imaging (MRI) apparatus including: a processor; an imaging device; a scanning bed; and a magnetic resonance transmitting coil including: a base, a coil shield arranged on the base, a transmitting coil arranged in the coil shield and configured to form an accommodating space to accommodate a subject, and a regulator connected with the transmitting coil and configured to adjust the transmitting coil according to a shape of the subject. The processor is configured to control the scanning bed to move the subject into the accommodating space of the magnetic resonance transmitting coil.

In some implementations, the transmitting coil includes: a coil body; a plurality of structural supports fixed on the coil body; and a guiderail disposed on respective peripheries of the structural supports. The regulator can be configured to adjust a distance between the transmitting coil and the subject by causing each of the structural supports to slide along the guiderail.

Before the transmitting coil is adjusted by the regulator, the structural supports can be distributed on the coil body in an equal spacing. When the accommodating space of the transmitting coil fits the shape of the subject, a spacing between two adjacent structural supports of the transmitting coil along an edge of the coil body can decrease gradually from a top of the coil body to a bottom of the coil body, and a distance from each portion of the coil body to the subject can be kept within a predetermined range.

The MRI apparatus can include one or more laser ranging devices disposed on the coil body and configured to measure a distance from a portion of the coil body to the subject. One of the laser ranging devices can be located at a top of the coil body. In some cases, the processor is configured to: process the distance data measured by the laser ranging devices, generate control instructions based on the processed distance data, and transmit the control instructions to the regulator, and the regulator is configured to adjust the distance between the transmitting coil and the subject based on the control instructions.

In some implementations, the regulator includes: a driving motor; a transmission wheel connected with the driving motor; and a transmission component connected with the transmission wheel and the coil body and configured such that, when the driving motor is controlled to drive the transmission wheel to rotate and then the transmission wheel drives the transmission component, the transmission component acts on the coil body to retract or release the coil body.

The details of one or more examples of the subject matter described in the present disclosure are set forth in the accompanying drawings and description below. Other features, aspects, and advantages of the subject matter will become apparent from the description, the drawings, and the claims. Features of the present disclosure are illustrated by way of example and not limited in the following figures, in which like numerals indicate like elements.

### BRIEF DESCRIPTION OF DRAWINGS

FIG. 1 illustrates an overall structural diagram of a magnetic resonance imaging apparatus and its magnetic resonance transmitting coil according to an example of the present disclosure.

FIG. 2 illustrates a diagram showing adjustment of a magnetic resonance transmitting coil according to an example of the present disclosure.

FIG. 3 illustrates a structural diagram of a magnetic resonance transmitting coil before adjustment according to an example of the present disclosure.

FIG. 4 illustrates a structural diagram of a magnetic resonance transmitting coil after adjustment according to an example of the present disclosure.

### DETAILED DESCRIPTION

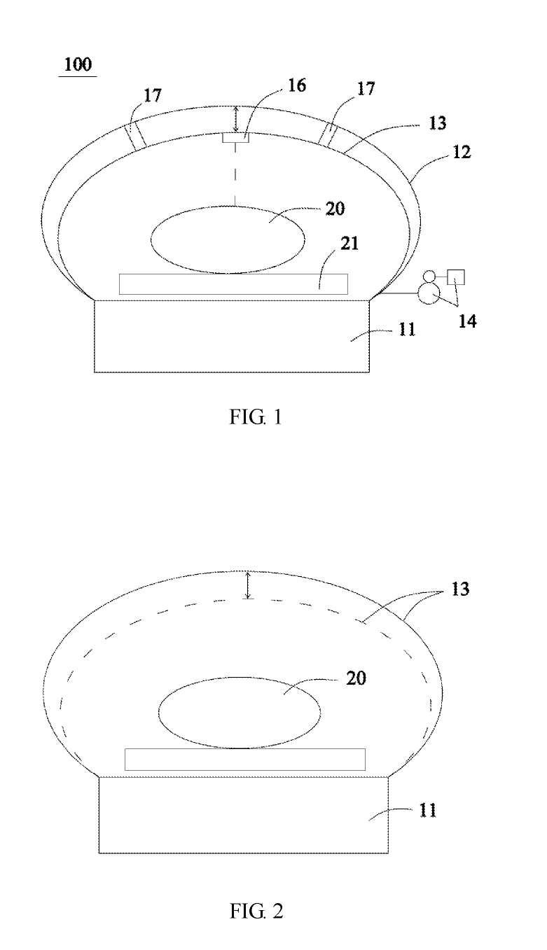

FIG. 1 illustrates an overall structure diagram of a magnetic resonance imaging apparatus 100 according to an example of the present disclosure, and FIG. 2 illustrates a diagram showing adjustment of a magnetic resonance transmitting coil according to an example of the present disclosure. The magnetic resonance transmitting coil 100 may include a base 11, a coil shield 12 fixed on the base 11, a transmitting coil 13 arranged in the coil shield 12 and a regulating mechanism 14 (or a regulator) connected with the transmitting coil 13. The transmitting coil 13 may have a particular flexibility so that the shape and size of the transmitting coil 13 may be adjusted by the regulating mechanism 14. The transmitting coil 13 may have an accommodating space to accommodate a subject 20, and the regulating mechanism 14 may be used to adjust the size of the accommodating space. Specifically, the transmitting coil 13 may be adjusted by the regulating mechanism 14 based on a shape, e.g., a body shape, of a subject 20 so that the accommodating space of the transmitting coil 13 may fit the shape of the subject 20. For example, the transmitting coil includes a plurality of portions, and each portion of the transmitting coil 13 may be adjusted to be closer to the subject 20 so that a distance between the subject 20 and each portion of the transmitting coil 13 may be kept within a range, thereby guaranteeing the safety of the subject 20 and maximizing the transmitting efficiency of the transmitting coil 13. The range can be predetermined.

In the present disclosure, the transmitting coil 13 may be of a D shape or an oval shape. Correspondingly, the coil shield 12 may also be of a D shape or an oval shape. The use of these shapes may not only allow the subject 20 to be moved into the accommodating space but also facilitate subsequent adjustment to the transmitting coil 13, thereby effectively reducing adjusting amplitude and adjustment difficulty of the transmitting coil 13.

As shown in FIGS. 1 to 4, the transmitting coil 13 may include a coil body 131, a plurality of structural supports 132 fixed to the coil body 131, e.g., in an equal spacing, and a guiderail (not shown) disposed in respective peripheries of the structural supports 132. Before the transmitting coil 13 is adjusted by the regulating mechanism 14, the plurality of structural supports 132 may be distributed on the coil body 131 in an equal spacing. When the transmitting coil 13 is adjusted by the regulating mechanism 14, each of the plurality of the structural supports 132 may be caused to slide along the guiderail to adjust a distance between the transmitting coil 13 and the subject 20. The transmitting coil 13 may be designed to have an overall flexibility so that the size of the accommodating space enclosed by the transmitting coil 13 may be controlled by using the flexibility of the transmitting coil 13. Specifically, when the transmitting coil 13 is being adjusted, a shape and size of the guiderail may also be changed along with the adjusting process. The plurality of structural supports 132 may be caused to slide along the guiderail by locally stretching and retracting the transmitting coil 13. For example, a portion of the transmitting coil 13 away from the subject 20 can be adjusted to get close to the subject 20 with a largest adjusting amplitude and other portions of the transmitting coil 13 can also be adjusted accordingly.

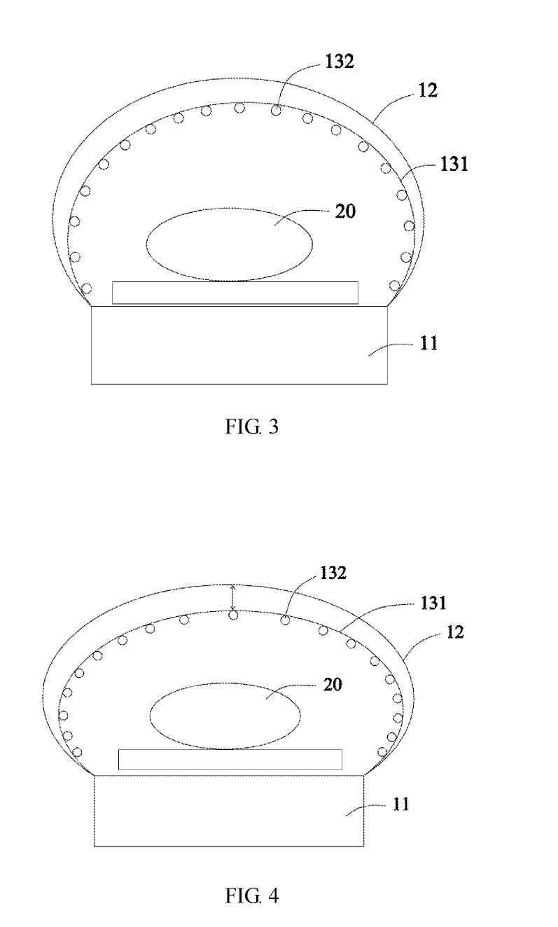

When the accommodating space of the transmitting coil 13 fits the body shape of the subject 20, the spacing between two adjacent structural supports 132 along an edge of the coil body 131 may gradually decrease from a top of the coil body 131 to a bottom of the coil body 131 as shown in FIG. 4. Amplitudes of distortion at each portion of the coil body 131 vary so that each of the structural supports 132 has a different adjusting amplitude to fit the body shape of the subject 20. As a result, a radio frequency field may be more uniform and the transmitting coil 13 may have an improved transmission efficiency. In an example, before the subject 20 is moved into the accommodating space of the transmitting coil 13, to make sure the transmitting coil 13 has a sufficiently large accommodating space for the subject 20 to be moved into, the accommodating space can be larger than the body shape of the subject 20. Therefore, in the example, the structural supports 132 on the transmitting coil 13 may be arranged uniformly, e.g., with an equal spacing, before adjustment of the transmitting coil 13 as shown in FIG. 3.

In an example of the present disclosure, when the accommodating space of the transmitting coil 13 fits the body shape of the subject 20, a distance from any portion of the coil body 131 to the subject 20 is the same. Specifically, the distance may be controlled to be within a proper range so that the radio frequency field produced by the transmitting coil 13 becomes more uniform and the transmission efficiency of the transmitting coil 13 reaches a maximum value.

In an example of the present disclosure, the regulating mechanism 14 may be placed near a magnet of the MRI apparatus or near the coil shield 12. The regulating mechanism 14 may include a driving motor (not shown), a transmission wheel (not shown) connected with the driving motor and a transmission component (not shown) connected with the transmission wheel and the coil body 131. In an example, the driving motor may be controlled to drive the transmission wheel to rotate and then the transmission wheel may drive the transmission component to act on the coil body 131 so that the coil body 131 may be retracted or released. Driven by the retraction or release of the coil body 131, the structural supports 132 fixed on the coil body 131 may be caused to slide along the guiderail. The transmission component may include a plurality of cables connected to a plurality of portions of the coil body 131 and may also include structural members (or structural connectors), e.g., fasteners or bolts, connected to the plurality of portions of the coil body 131.

Further, the transmitting coil 13 may also include one or more laser ranging devices (or distance measurement devices) 16 disposed on the coil body 131 and configured to measure a distance from a portion of the coil body 131 to the subject 20. In an example, a plurality of laser ranging devices 16 is disposed. The plurality of laser ranging devices 16 may be uniformly distributed on the transmitting coil 13 so that the laser ranging devices 16 may be used to measure the distance from the subject 20 to the transmitting coil 13 (or the coil body 131) and amplitudes by which the transmitting coil 13 is to be adjusted may be calculated. The laser ranging devices 16 may communicate with a processor of an MRI apparatus to transmit the measured data to the processor. The processor may generate and transmit control instructions to the regulating mechanism 14 after processing the measured data so that the regulating mechanism 14 may adjust the distance between the transmitting coil 13 and the subject 20 based on the control instructions. In this way, a minimum safety distance between the transmitting coil 13 and the subject 20 may be achieved with synergetic operation of the laser ranging devices 16.

In an example of the present disclosure, one of the laser ranging devices 16 is located at a top of the coil body 131. When there is only one laser ranging device 16, the laser ranging device 16 may be located at the top of the coil body 131; when there are a plurality of laser ranging devices 16, one of the plurality of the laser ranging devices 16 may be located at the top of the coil body 131 and the other laser ranging devices may be uniformly distributed on the coil body 131.

Further, the magnetic resonance transmitting coil 100 may also include a plurality of connectors 17 fixed between the transmitting coil 13 and the coil shield 12. The plurality of connectors 17 may be configured to keep a spacing between the transmitting coil 13 and the coil shield 12 to be fixed and may be uniformly distributed between the transmitting coil 13 and the coil shield 12. During an adjusting process of the transmitting coil 13, the spacing between the coil shield 12 and the structural supports 132 keeps unchanged, so as to achieve impedance continuity. In this way, during the adjusting process of the transmitting coil 13, a frequency of the transmitting coil 13 may remain constant without additionally adjusting a capacitance value of the transmitting coil 13. In an example, the transmitting coil 13 and the coil shield 12 may be firmly locked by the connectors 17 so that the transmitting coil 13 and the coil shield 12 may be moved upwards and downwards simultaneously (or together) with an invariable spacing.

As shown in FIG. 1, according to another aspect of the present disclosure, an MRI apparatus is also provided. The MRI apparatus may include: an imaging device (not shown), a scanning bed 21, and the magnetic resonance transmitting coil 100 as described above. Under the control of a processor of the MRI apparatus, the subject 20 is moved into an accommodating space of the magnetic resonance transmitting coil 100 by the scanning bed 21. According to the present disclosure, the magnetic resonance transmitting coil 100 can be adjusted to fit different body shapes so that the transmitting coil 13 may be closer to a human body, thereby obtaining a higher efficiency.

The term used in the present disclosure is for the purpose of describing a particular example only, and is not intended to be limiting of the present disclosure. The singular forms such as “a”, ‘said”, and “the” used in the present disclosure and the appended claims are also intended to include multiple, unless the context clearly indicates otherwise. It is also to be understood that the term “and/or” as used herein refers to any or all possible combinations that include one or more associated listed items.

It is to be understood that although different information may be described using the terms such as first, second, third, etc. in the present disclosure, the information should not be limited to these terms. These terms are used only to distinguish the same type of information from each other. For example, the first information may also be referred to as the second information without departing from the scope of the present disclosure, and similarly, the second information may also be referred to as the first information. Depending on the context, the word “if’ as used herein may be interpreted as “when” or “as” or “determining in response to”.

After considering the specification and practicing the present disclosure, the persons of skill in the prior art may easily conceive of other implementations of the present disclosure. The present disclosure is intended to include any variations, uses and adaptive changes of the present disclosure. These variations, uses and adaptive changes follow the general principle of the present disclosure and include common knowledge or conventional technical means in the prior art not disclosed in the present disclosure. The specification and examples herein are intended to be illustrative only and the real scope and spirit of the present disclosure are indicated by the claims of the present disclosure.

It is to be understood that the present disclosure is not limited to the precise structures described above and shown in the accompanying drawings and may be modified or changed without departing from the scope of the present disclosure. The scope of protection of the present disclosure is limited only by the appended claims.

1. A magnetic resonance transmitting coil comprising:
a base;
a coil shield arranged on the base;
a transmitting coil arranged in the coil shield and defining an accommodating space to accommodate a subject; and
a regulator connected with the transmitting coil and configured to adjust the transmitting coil according to a shape of the subject such that the accommodating space of the transmitting coil fits the shape of the subject.

2. The magnetic resonance transmitting coil of claim 1, wherein the transmitting coil comprises:
a coil body;
a plurality of structural supports arranged on the coil body; and
a guiderail disposed on respective peripheries of the structural supports,
wherein the regulator is configured to adjust a distance between the transmitting coil and the subject by causing at least one of the structural supports to slide along the guiderail.

3. The magnetic resonance transmitting coil of claim 2, wherein, before the transmitting coil is adjusted by the regulator, the structural supports are configured to be distributed on the coil body in an equal spacing.

4. The magnetic resonance transmitting coil of claim 3, wherein, when the accommodating space of the transmitting coil fits the shape of the subject, the spacing between two adjacent structural supports along an edge of the coil body decreases gradually from a top of the coil body to a bottom of the coil body.

5. The magnetic resonance transmitting coil of claim 3, wherein the coil body comprises a plurality of portions each being movable to the subject, and
wherein, when the accommodating space of the transmitting coil fits the shape of the subject, a distance from each portion of the coil body to the subject is kept within a predetermined range.

6. The magnetic resonance transmitting coil of claim 2, wherein at least one of a shape or a size of the guiderail is changeable along with the adjustment of the transmitting coil.

7. The magnetic resonance transmitting coil of claim 2, wherein the plurality of structural supports is configured to slide along the guiderail by locally stretching and retracting the transmitting coil.

8. The magnetic resonance transmitting coil of claim 2, wherein the regulator comprises:
a driving motor;
a transmission wheel connected with the driving motor; and
a transmission component connected with the transmission wheel and the coil body.

9. The magnetic resonance transmitting coil of claim 8, wherein the transmission component comprises one of
a plurality of cables connected to a plurality of portions of the coil body, and
structural connectors connected to the plurality of portions of the coil body.

10. The magnetic resonance transmitting coil of claim 8, wherein the transmission component is configured such that, when the driving motor is controlled to drive the transmission wheel to rotate and then the transmission wheel drives the transmission component, the transmission component acts on the coil body to retract or release the coil body.

11. The magnetic resonance transmitting coil of claim 1, further comprising:
one or more laser ranging devices disposed on the coil body and each configured to measure a distance from a portion of the coil body to the subject.

12. The magnetic resonance transmitting coil of claim 11, wherein one of the laser ranging devices is located at a top of the coil body.

13. The magnetic resonance transmitting coil of claim 1, further comprising a plurality of connectors fixed between the transmitting coil and the coil shield,
wherein the connectors are configured to keep a spacing between the transmitting coil and the coil shield to be fixed.

14. The magnetic resonance transmitting coil of claim 1, wherein a shape of the transmitting coil comprises a D shape or an oval shape.

15. A magnetic resonance imaging (MRI) apparatus comprising:
a processor;
an imaging device;
a scanning bed; and
a magnetic resonance transmitting coil comprising:
a base,
a coil shield arranged on the base,
a transmitting coil arranged in the coil shield and configured to form an accommodating space to accommodate a subject, and
a regulator connected with the transmitting coil and configured to adjust the transmitting coil according to a shape of the subject,
wherein the processor is configured to control the scanning bed to move the subject into the accommodating space of the magnetic resonance transmitting coil.

16. The MRI apparatus of claim 15, wherein the transmitting coil includes:
a coil body;
a plurality of structural supports fixed on the coil body; and
a guiderail disposed on respective peripheries of the structural supports;
wherein the regulator is configured to adjust a distance between the transmitting coil and the subject by causing at least one of the structural supports to slide along the guiderail.

17. The MRI apparatus of claim 16, wherein, before the transmitting coil is adjusted by the regulator, the structural supports are distributed on the coil body in an equal spacing, and
wherein, when the accommodating space of the transmitting coil fits the shape of the subject, a spacing between two adjacent structural supports of the transmitting coil along an edge of the coil body decreases gradually from a top of the coil body to a bottom of the coil body, and a distance from each portion of the coil body to the subject is kept within a predetermined range.

18. The MRI apparatus of claim 15, further comprising one or more laser ranging devices disposed on the coil body and configured to measure a distance from a portion of the coil body to the subject, wherein one of the laser ranging devices is located at a top of the coil body.

19. The MRI apparatus of claim 18, wherein the processor is configured to:
process the distance data measured by the laser ranging devices,
generate control instructions based on the processed distance data, and
transmit the control instructions to the regulator, and
wherein the regulator is configured to adjust the distance between the transmitting coil and the subject based on the control instructions.

20. The MRI apparatus of claim 15, wherein the regulator comprises:
a driving motor;
a transmission wheel connected with the driving motor; and
a transmission component connected with the transmission wheel and the coil body and configured such that, when the driving motor is controlled to drive the transmission wheel to rotate and then the transmission wheel drives the transmission component, the transmission component acts on the coil body to retract or release the coil body.
